(19) United States
(12) Patent Application Publication
(10) Pub. No.: US 2022/0374575 A1
(43) Pub. Date: Nov. 24, 2022

(54) ELECTRONIC-PHOTONIC PROCESSORS AND RELATED PACKAGES

(71) Applicant: Lightmatter, Inc., Boston, MA (US)

(72) Inventors: Carl Ramey, Westborough, MA (US); Nicholas C. Harris, Boston, MA (US); Hamid Eslampour, San Jose, CA (US)

(73) Assignee: Lightmatter, Inc., Boston, MA (US)

(21) Appl. No.: 17/748,916

(22) Filed: May 19, 2022

Related U.S. Application Data
(60) Provisional application No. 63/192,519, filed on May 24, 2021.
(60) Provisional application No. 63/191,278, filed on May 20, 2021.

(51) Int. Cl. G06F 30/38

(52) U.S. Cl. CPC G06F 30/38

(57) ABSTRACT

Electronic-photonic packages and related fabrication methods are described. A package may include a plurality of photonic integrated circuits (PICs), where each PIC comprises a photonic accelerator configured to perform matrix multiplication in the optical domain. The package may further include an application specific integrated circuit (ASIC) configured to control at least one of the photonic accelerators. The package further includes an interposer. The plurality of PICs are coupled to a first side of the interposer and the ASIC is coupled to a second side of the interposer opposite the first side. A first thermally conductive member in thermal contact with at least one of the PICs. The first thermally conductive member may include a heat spreader. A second thermally conductive member in thermal contact with the ASIC. The second thermally conductive member may include a lid. The first thermally conductive member faces the first side of the interposer, and the second thermally conductive member faces the second side of the interposer. In some embodiments, the interposer sits in part on a substrate and in part on the PICs.

### CROSS-REFERENCE TO RELATED APPLICATION

This application claims the benefit under 35 U.S.C. § 119(e) of U.S. Provisional Patent Application Ser. No. 63/192,519, entitled “OPTICAL COMPUTE NODE,” filed on May 24, 2021, under Attorney Docket No. L0858.70042US01, and U.S. Provisional Patent Application Ser. No. 63/191,278, entitled “OPTICAL COMPUTE NODE,” filed on May 20, 2021, under Attorney Docket No. L0858.70042US00, each of which is hereby incorporated herein by reference in its entirety.

### BACKGROUND

Deep learning, machine learning, latent-variable models, neural networks and other matrix-based differentiable programs are used to solve a variety of problems, including natural language processing and object recognition in images. Solving these problems with deep neural networks typically requires long processing times to perform the required computation. The conventional approach to speed up deep learning algorithms has been to develop specialized hardware architectures. This is because conventional computer processors, e.g., central processing units (CPUs), which are composed of circuits including hundreds of millions of transistors to implement logical gates on bits of information represented by electrical signals, are designed for general purpose computing and are therefore not optimized for the particular patterns of data movement and computation required by the algorithms that are used in deep learning and other matrix-based differentiable programs. One conventional example of specialized hardware for use in deep learning are graphics processing units (GPUs) having a highly parallel architecture that makes them more efficient than CPUs for performing image processing and graphical manipulations. After their development for graphics processing, GPUs were found to be more efficient than CPUs for other parallelizable algorithms, such as those used in neural networks and deep learning. This realization, and the increasing popularity of artificial intelligence and deep learning, led to further research into new electronic circuit architectures that could further enhance the speed of these computations.

Deep learning using neural networks conventionally requires two stages: a training stage and an evaluation stage (sometimes referred to as “inference”). Before a deep learning algorithm can be meaningfully executed on a processor, e.g., to classify an image or speech sample, during the evaluation stage, the neural network must first be trained. The training stage can be time consuming and requires intensive computation.

### SUMMARY OF THE DISCLOSURE

Some embodiments relate to an electronic-photonic package comprising: a substrate having an opening defined therethrough; an application specific integrated circuit (ASIC) and a photonic integrated circuit (PIC), wherein a first chip between the ASIC and the PIC is disposed in the opening; an interposer, wherein the first chip is coupled to a first side of the interposer and a second chip between the ASIC and the PIC is coupled to a second side of the interposer opposite the first side; a heat spreader disposed in the opening and in thermal contact with the first chip; and a thermally conductive lid in thermal contact with the second chip.

In some embodiments, the opening is defined from a top surface of the substrate to a bottom surface of the substrate.

In some embodiments, the first chip is the PIC and the second chip is the ASIC, such that the heat spreader is in thermal contact with the PIC and the thermally conductive lid is in thermal contact with the ASIC.

In some embodiments, the first chip is disposed at least partially in the opening.

In some embodiments, the thermally conductive lid has a fiber passage defined therethrough.

In some embodiments, a fiber passing through the fiber passage is configured to edge couple to the PIC.

In some embodiments, the substrate has a top surface facing the interposer and a bottom surface, wherein the electronic-photonic package further comprise land grid array (LGA) pads coupled to the bottom surface of the substrate.

In some embodiments, the interposer comprises a silicon interposer or an organic interposer.

In some embodiments, the PIC comprises a photonic accelerator configured to perform matrix multiplication in an optical domain, and wherein the ASIC comprises a digital controller configured to control the photonic accelerator.

In some embodiments, the electronic-photonic package lacks lasers disposed therein.

Some embodiments relate to an electronic-photonic processor comprising a plurality of photonic integrated circuits (PICs), each PIC comprising a photonic accelerator configured to perform matrix multiplication in an optical domain; an application specific integrated circuit (ASIC) configured to control at least one of the photonic accelerators; an interposer, wherein the plurality of PICs are coupled to a first side of the interposer and the ASIC is coupled to a second side of the interposer opposite the first side; a first thermally conductive member in thermal contact with at least one of the PICs; and a second thermally conductive member in thermal contact with the ASIC, wherein the first thermally conductive member faces the first side of the interposer, and the second thermally conductive member faces the second side of the interposer.

In some embodiments, the electronic-photonic processor further comprises a substrate having an opening formed therethrough, wherein the interposer is mounted on the substrate, and wherein either the first thermally conductive member or the second thermally conductive member is disposed in the opening.

In some embodiments, the substrate has a top surface facing the interposer and a bottom surface, wherein the electronic-photonic processor further comprise land grid array (LGA) pads coupled to the bottom surface of the substrate.

In some embodiments, the second thermally conductive member is in contact with the substrate.

In some embodiments, the interposer comprises a silicon interposer or an organic interposer.

In some embodiments, the digital controller is configured to control the photonic accelerators to perform matrix multiplication in the optical domain in parallel on a tile-by-tile basis.

In some embodiments, the photonic accelerators comprise photonic multipliers configured to perform scalar multiplications in the optical domain.

In some embodiments, the photonic accelerators comprise photonic adders configured to perform scalar additions in the optical domain.

In some embodiments, the plurality of PICs, the ASIC, the interposer, and the first and second thermally conductive members form a package, and wherein the electronic-photonic processor further comprises a laser disposed outside the package.

In some embodiments, the first thermally conductive member comprises conductive pillars.

Some embodiments relate to an electronic-photonic package comprising a substrate; a photonic integrated circuit (PIC) supported by the substrate; an interposer sitting in part on the substrate and in part on the PIC; a first set of connections coupling the interposer to the substrate and a second set of connections coupling the interposer to the PIC, wherein the first set of connections have different sizes with respect to the second set of connections; and an application specific integrated circuit (ASIC) disposed on the interposer.

In some embodiments, the electronic-photonic package further comprises a thermally conductive lid in thermal contact with the ASIC.

In some embodiments, the first set of interconnections is a ball grid array (BGA).

In some embodiments, the first set of connections are larger than the second set of connections.

In some embodiments, the substrate has an opening defined therethrough, and wherein the PIC is disposed in the opening.

Some embodiments relate to a method for fabricating an electronic-photonic package, comprising: obtaining a substrate, an application-specific integrated circuit (ASIC), a photonic integrated circuit (PIC) and an interposer; forming an interposer module by attaching the ASIC to a first side of the interposer and the PIC to a second side of the interposer; attaching the interposer module to the substrate; placing a first thermally conductive member in thermal contact with the ASIC; and placing a second thermally conductive member in thermal contact with the PIC.

In some embodiments, the method further comprises forming a first underfill on the first side of the interposer; flipping the interposer; and subsequent to flipping, forming a second underfill on the second side of the interposer.

In some embodiments, placing the second thermally conductive member in thermal contact with the PIC comprises inserting the second thermally conductive member through an opening formed in the substrate.

In some embodiments, the method further comprising flipping the substrate, so that placing the first thermally conductive member in thermal contact with the ASIC is performed prior to flipping the substrate and placing the second thermally conductive member in thermal contact with the PIC is performed after flipping the substrate.

### BRIEF DESCRIPTION OF DRAWINGS

Various aspects and embodiments of the application will be described with reference to the following figures. It should be appreciated that the figures are not necessarily drawn to scale. Items appearing in multiple figures are indicated by the same reference number in the figures in which they appear.

FIG. 1A illustrates a representative matrix-vector multiplication, in accordance with some embodiments.

FIG. 1B is a block diagram illustrating an electronic-photonic processor configured to perform matrix-vector multiplication, in accordance with some embodiments.

FIG. 1C is a block diagram illustrating a portion of the photonic accelerator of FIG. 1B, in accordance with some embodiments.

FIG. 2A illustrates a representative matrix-vector multiplication performed on a tile-by-tile basis, in accordance with some embodiments.

FIG. 2B is a block diagram of an electronic-photonic processor configured to perform matrix-vector multiplication on a tile-by-tile basis, in accordance with some embodiments.

FIG. 2C is a schematic diagram of an electronic-photonic processor having an interposer, in accordance with some embodiments.

FIG. 3A is a first cross sectional view of a package hosting an electronic-photonic processor, in accordance with some embodiments.

FIG. 3B is a second cross sectional view of a package hosting an electronic-photonic processor, in accordance with some embodiments.

FIG. 3C is a top view of a package hosting an electronic-photonic processor, in accordance with some embodiments.

FIG. 3D is a perspective view of a package hosting an electronic-photonic processor, in accordance with some embodiments.

FIG. 4 is a cross sectional view of a package mounted to a printed circuit board via a socket, in accordance with some embodiments.

FIG. 5 is a first cross sectional view of another package hosting an electronic-photonic processor, in accordance with some embodiments.

FIG. 6 is a flowchart illustrating a process for fabricating an electronic-photonic package, in accordance with some embodiments.

### DETAILED DESCRIPTION

### I. Overview

The inventors have recognized and appreciated that photonic accelerators are susceptible to temperature variations resulting from the production of heat in the photonic accelerators themselves or the electronic circuits that control them. The inventors have developed packages designed to spread the heat in a way that limits temperature variations.

The proper functioning of a photonic accelerator relies heavily on the refractive index to remain relatively constant over time. The refractive index of a material—a dimensionless number that describes how fast light travels through the material—is a critically important parameter for the design of a photonic circuit in that it determines how light propagates in the material. This is because the propagation constant of a mode defined in an optical waveguide depends directly on the refractive index. The ability to accurately control the refractive index of a material allows engineers to control, modulate and steer light, among other functions. The refractive index of a material can be varied by leveraging the plasma dispersion effect (by altering the density of carriers in the material), among other effects. Thus, the refractive index can be varied intentionally to obtain desired effects. However, undesired refractive index variations may also occur, for example due to heat. When a photonic accelerator is exposed to heat, whether produced from the photonic accelerator itself or other chips, the refractive index varies in an unpredictable fashion, thus altering the properties of the optical modes. This negatively impacts the performance of a photonic accelerator.

Although a photonic accelerator itself can produce heat, this heat is typically smaller than the heat produced by the digital controllers that control the photonic accelerators. This is because electronic circuits are susceptible to parasitic capacitance, which lead to power dissipation and as a result production of heat via the Joule effect. To the contrary, by nature, photonic circuits are not susceptible to parasitic capacitance. In one example, a photonic accelerator operates at 1 W and the digital controller that controls it operates at 100 W—thereby producing significantly more heat.

Having appreciated that heat produced by a digital controller represents that main disruptor to the proper functioning of a photonic accelerator, the inventors have developed package engineered to spread the heat away from the photonic accelerator. In some embodiments, for example, a package is provided that includes an interposer with photonic integrated circuits (PICs) and application-specific integrated circuits (ASICs) attached thereto. The PICs include photonic accelerators, and the ASICs include digital controllers. The PICs may be disposed on one side of the interposer (e.g., the bottom side), the PICs may be disposed on the opposite side of the interposer (e.g., the top side), and heat produced by the heat may be spread away from the PICs, thereby limiting heat-induced refractive index variations.

The PICs also produce some heat. Although it is significantly less than the heat produced by the ASICs, this heat can also lead to undesired variations in refractive index. Thus, it is important that this heat also be spread outside the package. The packages developed by the inventors spread the heat produced by the PICs in the opposite direction relative to the heat produced by the ASICs. This can be accomplished for example by placing thermally conductive members on opposite sides of the package.

### II. Electronic-Photonic Processors

Aspects of the present application relate to analog accelerators configured to execute neural networks. Accelerators are microprocessors that are capable of accelerating certain types of workloads. Typically, workloads that can be accelerated are offloaded to high-performance accelerators, which are much more efficient at performing workloads such as artificial intelligence, machine vision, and deep learning. Accelerators are specific purpose processors and are often programmed to work in conjunction with general purpose processors to perform a task. Analog accelerators are accelerators that perform computations in the analog domain. As such, analog accelerators typically involve digital-to-analog conversion and analog-to-digital conversion, which allow an analog accelerator to communicate with digital hardware.

Photonic accelerators are a particular class of analog accelerators in which computations are performed in the optical domain (using light). The inventors have recognized and appreciated that using optical signals (instead of, or in combination with, electrical signals) overcomes some of the problems with electronic computing. Optical signals travel at the speed of light. Thus, the latency of optical signals is far less of a limitation than electrical propagation delay. Additionally, virtually no power is dissipated by increasing the distance traveled by the light signals, opening up new topologies and processor layouts that would not be feasible using electrical signals. Thus, photonic processors offer far better speed and efficiency performance than conventional electronic processors.

Some embodiments relate to photonic accelerators designed to run machine learning algorithms or other types of data-intensive computations. Certain machine learning algorithms (e.g., support vector machines, artificial neural networks and probabilistic graphical model learning) rely heavily on linear transformations on multi-dimensional arrays/tensors. The simplest linear transformation is a matrix-vector multiplication, which using conventional algorithms has a complexity on the order of 0(N²), where N is the dimensionality of a square matrix being multiplied by a vector of the same dimension. General matrix-matrix (GEMM) operations are ubiquitous in software algorithms, including those for graphics processing, artificial intelligence, neural networks and deep learning.

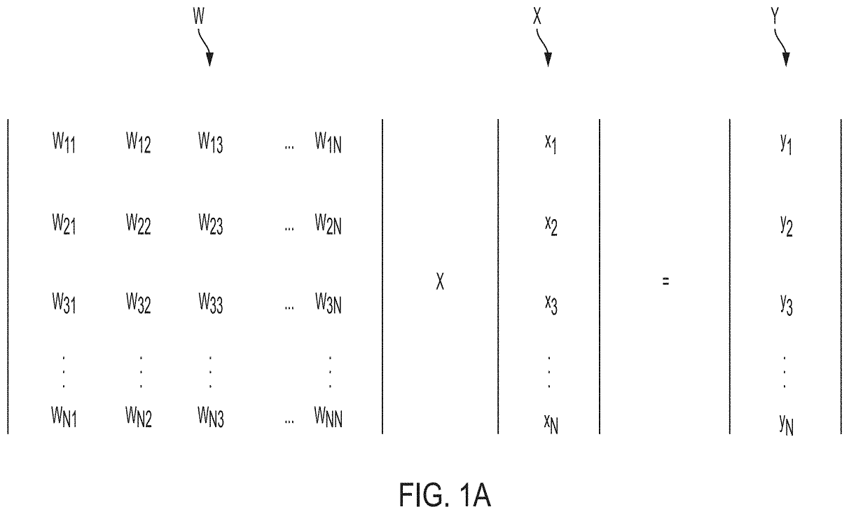

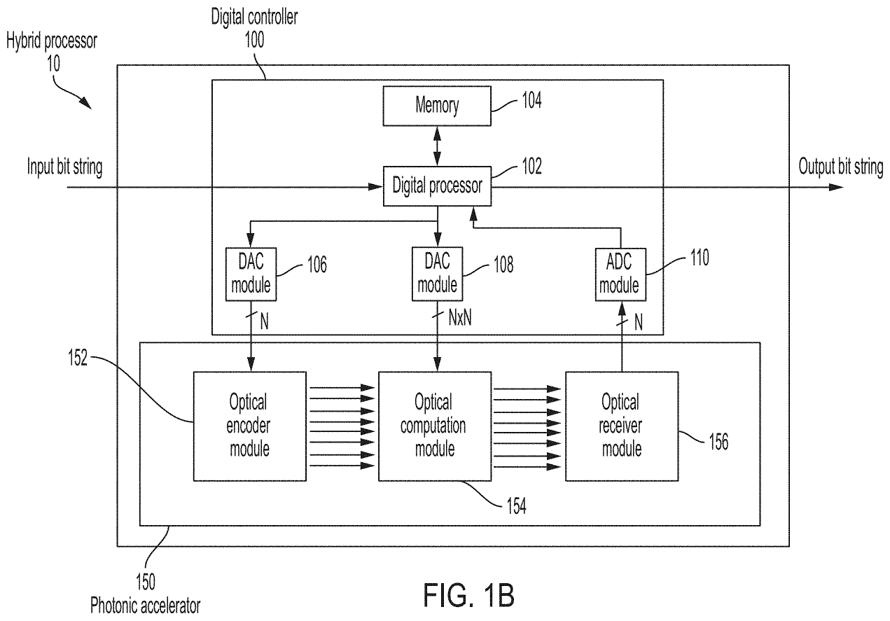

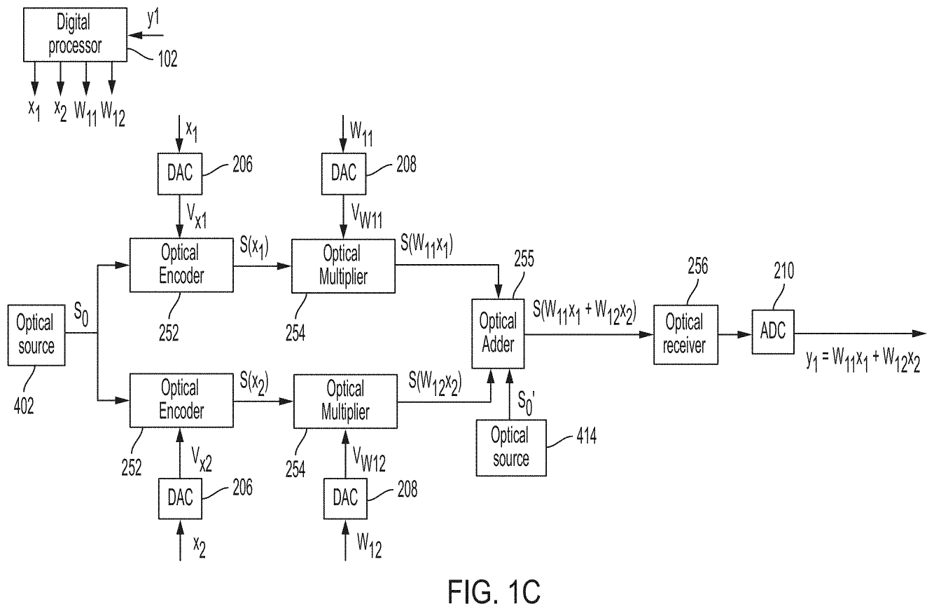

FIG. 1A is a representation of a matrix-vector multiplication, in accordance with some embodiments. Matrix-vector multiplication is an example of GEMM. Matrix W is referred to herein as “weight matrix,” “input matrix” or simply “matrix,” and the individual elements of matrix W are referred to herein as “weights,” “matrix values” or “matrix parameters.” Vector X is referred to herein as “input vector,” and the individual elements of vector X are referred to as “input values,” or simply “inputs.” Vector Y is referred to herein as “output vector,” and the individual elements of vector Y are referred to as “output values,” or simply “outputs.” In this example, W is an N×N matrix, though embodiments of the present application are not limited to square matrices or to any specific dimension. In the context of artificial neural networks, matrix W can be a weight matrix, or a block of submatrix of the weight tensor, or an activation (batched) matrix, or a block of submatrix of the (batched) activation tensor, among several possible examples. Similarly, the input vector X can be a vector of the weight tensor or a vector of the activation tensor, for example.

The matrix-vector multiplication of FIG. 1A can be decomposed in terms of scalar multiplications and scalar additions. For example, an output value yᵢ, (where i=1, 2 . . . N) can be computed as a linear combination of the input values x₁, x₂ . . . x_{N}. Obtaining yᵢ involves performing scalar multiplications (e.g., Wᵢ₁ times x₁, and Wᵢ₂ times x₂) and scalar additions (e.g., Wᵢ₁x₁ plus Wᵢ₂x₂). In some embodiments, scalar multiplications, scalar additions, or both, may be performed in the optical domain, as discussed in detail further below.

FIG. 1B illustrates an electronic-photonic processor 10 implemented using photonic circuits, in accordance with some embodiments. Processor 10 may be configured to perform matrix multiplications (e.g., matrix-vector multiplications or matrix-matrix multiplications). Processor 10 includes a digital controller 100 and a photonic accelerator 150. Digital controller 100 operates in the digital domain and photonic accelerator 150 operates in the analog photonic domain.

Digital controller 100 includes a digital processor 102 and a memory 104. Photonic accelerator 150 includes an optical encoder module 152, an optical computation module 154 and an optical receiver module 156. Digital-to-analog (DAC) modules 106 and 108 convert digital data to analog signals. Analog-to-digital (ADC) module 110 converts analog signals to digital values. Thus, the DAC/ADC modules provide an interface between the digital domain and the analog domain. In this example, DAC module 106 produces N analog signals (one for each entry of an input vector), DAC module 108 produces N×N analog signals (one for each entry of a matrix), and ADC module 110 receives N analog signals (one for each entry of an output vector). Although matrix W is square in this example, it may be rectangular in some embodiments, such that the size of the output vector differs from the size of the input vector.

Processor 10 receives, as an input from an external processor (e.g., a CPU), an input vector represented by a group of input bit strings and produces an output vector represented by a group of output bit strings. For example, if the input vector is an N-dimensional vector, the input vector may be represented by N separate bit strings, each bit string representing a respective component of the vector. The input bit string may be received as an electrical signal from the external processor and the output bit string may be transmitted as an electrical signal to the external processor. In some embodiments, digital processor 102 does not necessarily output an output bit string after every process iteration. Instead, the digital processor 102 may use one or more output bit strings to determine a new input bit stream to feed through the components of the processor 10. In some embodiments, the output bit string itself may be used as the input bit string for a subsequent iteration of the process implemented by the processor 10. In other embodiments, multiple output bit streams are combined in various ways to determine a subsequent input bit string. For example, one or more output bit strings may be summed together as part of the determination of the subsequent input bit string.

DAC module 106 is configured to convert digital data into analog signals. The optical encoder module 152 is configured to convert the analog signals into optically encoded information to be processed by the optical computation module 154. The information may be encoded in the amplitude, phase and/or frequency of an optical pulse. Accordingly, optical encoder module 152 may include optical amplitude modulators, optical phase modulators and/or optical frequency modulators. In some embodiments, the optical signal represents the value and sign of the associated bit string as an amplitude and a phase of an optical pulse. In some embodiments, the phase may be limited to a binary choice of either a zero phase shift or a π phase shift, representing a positive and negative value, respectively. Embodiments are not limited to real input vector values. Complex vector components may be represented by, for example, using more than two phase values when encoding the optical signal.

The optical encoder module 152 outputs N separate optical pulses that are transmitted to the optical computation module 154. Each output of the optical encoder module 152 is coupled one-to-one to an input of the optical computation module 154. In some embodiments, the optical encoder module 152 may be disposed on the same substrate as the optical computation module 154 (e.g., the optical encoder module 152 and the optical computation module 154 are on the same chip). In such embodiments, the optical signals may be transmitted from the optical encoder module 152 to the optical computation module 154 in waveguides, such as silicon photonic waveguides.

The optical computation module 154 performs the multiplication of an input vector X by a matrix W. In some embodiments, optical computation module 154 includes multiple optical multipliers each configured to perform a scalar multiplication between an entry of the input vector and an entry of matrix W in the optical domain. Optionally, optical computation module 154 may further include optical adders for adding the results of the scalar multiplications to one another in the optical domain. Alternatively, the additions may be performed electrically. For example, optical receiver module 156 may produce a voltage resulting from the integration (over time) of a photocurrent received from a photodetector.

The optical computation module 154 outputs N separate optical pulses that are transmitted to the optical receiver module 156. Each output of the optical computation module 154 is coupled one-to-one to an input of the optical receiver module 156. In some embodiments, the optical computation module 154 may be disposed on the same substrate as the optical receiver module 156 (e.g., the optical computation module 154 and the optical receiver module 156 are on the same chip). In such embodiments, the optical signals may be transmitted from the optical computation module 154 to the optical receiver module 156 in silicon photonic waveguides. In other embodiments, the optical computation module 154 may be disposed on a separate substrate from the optical receiver module 156. In such embodiments, the optical signals may be transmitted from the photonic processor 103 to the optical receiver module 156 using optical fibers.

The optical receiver module 156 receives the N optical pulses from the optical computation module 154. Each of the optical pulses is then converted to an electrical analog signal. In some embodiments, the intensity and phase of each of the optical pulses is detected by optical detectors within the optical receiver module. The electrical signals representing those measured values are then converted into the digital domain using ADC module 110, and provided back to the digital processor 102.

The digital processor 102 controls the optical encoder module 152, the optical computation module 154 and the optical receiver module 156. The memory 104 may be used to store input and output bit strings and measurement results from the optical receiver module 156. The memory 104 also stores executable instructions that, when executed by the digital processor 102, control the optical encoder module 152, optical computation module 154 and optical receiver module 156. The memory 104 may also include executable instructions that cause the digital processor 102 to determine a new input vector to send to the optical encoder based on a collection of one or more output vectors determined by the measurement performed by the optical receiver module 156. In this way, the digital processor 102 can control an iterative process by which an input vector is multiplied by multiple matrices by adjusting the settings of the optical computation module 154 and feeding detection information from the optical receiver module 156 back to the optical encoder module 152. Thus, the output vector transmitted by the processor 10 to the external processor may be the result of multiple matrix-matrix multiplications, not simply a single matrix-matrix multiplication.

FIG. 1C illustrates a portion of photonic accelerator 150 in additional detail, in accordance with some embodiments. More specifically, FIG. 1C illustrates the circuitry for computing y₁, the first entry of output vector Y. For simplicity, in this example, the input vector has only two entries, x₁ and x₂. However, the input vector may have any suitable size.

DAC module 106 includes DACs 206, DAC module 108 includes DACs 208, and ADC module 110 includes ADC 210. DACs 206 produce electrical analog signals (e.g., voltages or currents) based on the value that they receive. For example, voltage V_{X1} represents value x₁, voltage V_{X2} represents value x₂, voltage V_{W11} represents value W₁₁, and voltage V_{W12} represents value W₁₂. Optical encoder module 152 includes optical encoders 252, optical computation module 154 includes optical multipliers 154 and optical adder 255, and optical receiver module 156 includes optical receiver 256.

Optical source 402 produces light S₀. Optical source 402 may be implemented in any suitable way. For example, optical source 402 may include a laser, such as an edge-emitting laser of a vertical cavity surface emitting laser (VCSEL), examples of which are described in detail further below. In some embodiments, optical source 402 may be configured to produce multiple wavelengths of light, which enables optical processing leveraging wavelength division multiplexing (WDM), as described in detail further below. For example, optical source 402 may include multiple laser cavities, where each cavity is specifically sized to produce a different wavelength.

The optical encoders 252 encode the input vector into a plurality of optical signals. For example, one optical encoder 252 encodes input value x₁ into optical signal S(x₁) and another optical encoder 252 encodes input value x₂ into optical signal S(x₂). Input values xi and x₂, which are provided by digital processor 102, are digital signed real numbers (e.g., with a floating point or fixed point digital representation). The optical encoders modulate light S₀ based on the respective input voltage. For example, optical encoder 404 modulates amplitude, phase and/or frequency of the light to produce optical signal S(x₁) and optical encoder 406 modulates the amplitude, phase and/or frequency of the light to produce optical signal S(x₂). The optical encoders may be implemented using any suitable optical modulator, including for example optical intensity modulators. Examples of such modulators include Mach-Zehnder modulators (MZM), Franz-Keldysh modulators (FKM), resonant modulators (e.g., ring-based or disc-based), nano-electro-electro-mechanical-system (NOEMS) modulators, etc.

The optical multipliers are designed to produce signals indicative of a product between an input value and a matrix value. For example, one optical multiplier 254 produces a signal S(W₁₁x₁) that is indicative of the product between input value x₁ and matrix value A₁₁ and another optical multiplier 254 produces a signal S(W₁₂x₂) that is indicative of the product between input value x₂ and matrix value Wiz. Examples of optical multipliers include Mach-Zehnder modulators (MZM), Franz-Keldysh modulators (FKM), resonant modulators (e.g., ring-based or disc-based), nano-electro-electro-mechanical-system (NOEMS) modulators, etc. In one example, an optical multiplier may be implemented using a modulatable detector. Modulatable detectors are photodetectors having a characteristic that can be modulated using an input voltage. For example, a modulatable detector may be a photodetector with a responsivity that can be modulated using an input voltage. In this example, the input voltage (e.g., V_{W11}) sets the responsivity of the photodetector. The result is that the output of a modulatable detector depends not only on the amplitude of the input optical signal but also on the input voltage. If the modulatable detector is operated in its linear region, the output of a modulatable detector depends on the product of the amplitude of the input optical signal and the input voltage (thereby achieving the desired multiplication function).

Optical adder 412 receives electronic analog signals S(W₁₁x₁) and S(W₁₂x₂) and light S₀′ (generated by optical source 414), and produces an optical signal S(W₁₁x₁+W₁₂x₂) that is indicative of the sum of W₁₁x₁ with W₁₂x₂.

Optical receiver 256 generates an electronic digital signal indicative of the sum W₁₁x₁+W₁₂x₂ based on the optical signal S(W₁₁x₁+W₁₂x₂). In some embodiments, optical receiver 256 includes a coherent detector and a trans-impedance amplifier. The coherent detector produces an output that is indicative of the phase difference between the waveguides of an interferometer. Because the phase difference is a function of the sum W₁₁x₁+W₁₂x₂, the output of the coherent detector is also indicative of that sum. The ADC converts the output of the coherent receiver to output value y₁=W₁₁x₁+W₁₂x₂. Output value y₁ may be provided as input back to digital processor 102, which may use the output value for further processing.

### III. Parallel Computing

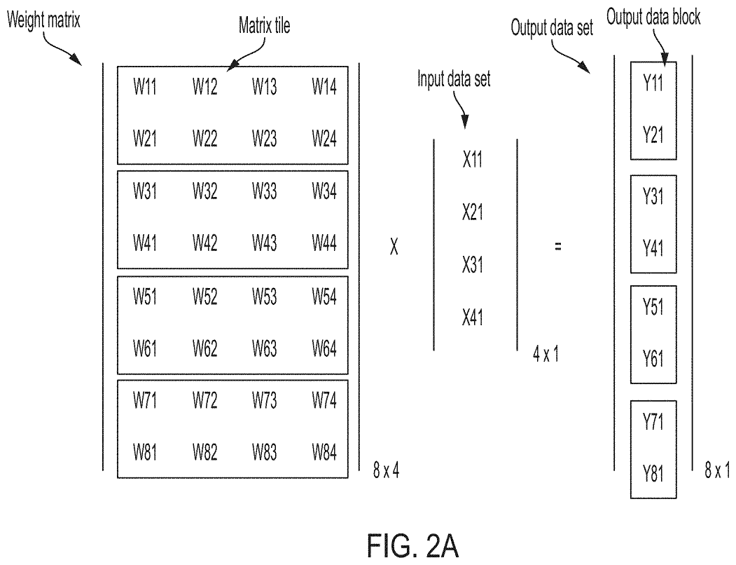

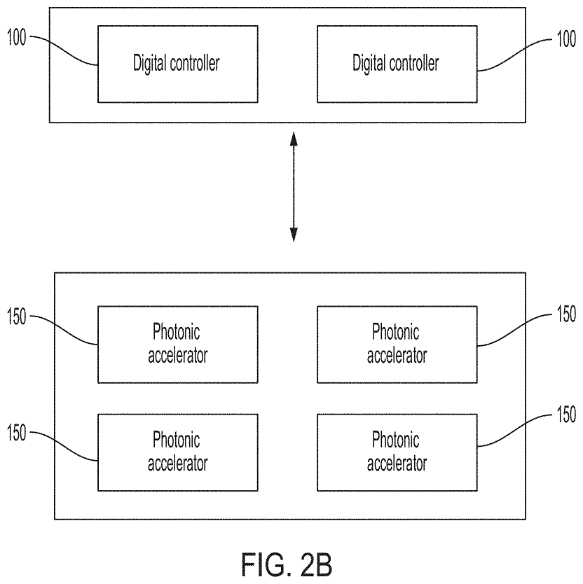

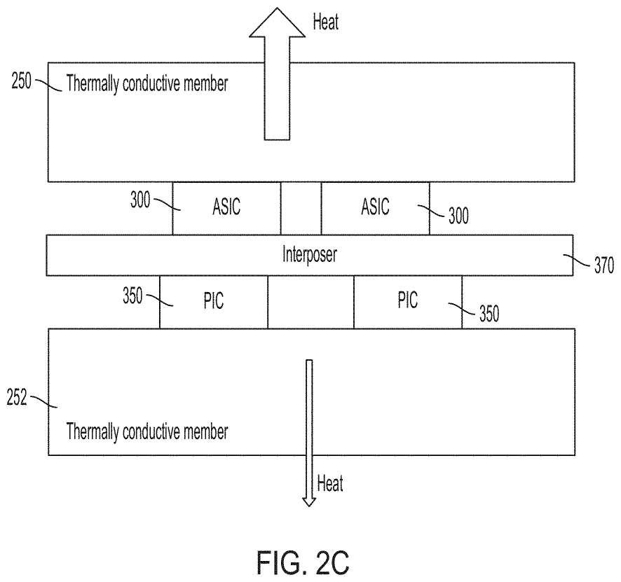

Some applications rely on the computation of massive amounts of data. In some embodiments, photonic accelerators run in a parallel fashion may be used to handle these applications. For example, a matrix to be multiplied by a vector may be broken down in tiles. FIG. 2A illustrates an example of how a matrix may be broken down in tiles, and each tile may be processed by a different photonic accelerator. In this way, multiple tiles can be processed in parallel. The diagram of FIG. 2A depicts a matrix that has been segmented in four tiles. In this example, performing matrix-vector multiplication involves 1) multiplying the first matrix tile by the input data vector to obtain a first output data block; 2) multiplying the second matrix tile by the input data vector to obtain a second output data block; 3) multiplying the third matrix tile by the input data vector to obtain a third output data block; and 4) multiplying the fourth matrix tile by the input data vector to obtain a fourth output data block. The output data block, collectively, form the output vector. Each tile multiplication can be handled by a different photonic accelerator. While this example illustrates an 8×4 weight matrix and a 4×1 input data set, any suitable dimension is possible.

Thus, some embodiments relate to computing systems including multiple photonic accelerators. One such example is illustrated in FIG. 2B. The computing system shown here includes four photonic accelerators 150 and two digital controllers 100. In some embodiments, each photonic accelerator is formed as an individual chip—referred to herein as a photonic integrated circuit (PIC). Similarly, in some embodiments, each digital controller is formed as an individual chip—referred to herein as an application-specific integrated circuit (ASIC). Thus, in some embodiments, a computing systems includes multiple PICs and multiple ASICs.

The inventors have recognized that packaging multiple ASICs with multiple PICs is challenging. In order to reduce real estate, the inventors have appreciated that the ASICs should be co-packaged with the PICs in the same assembly. Co-packaging, however, poses a challenge from a heat extraction perspective. PICs are particularly sensitive to temperature variations. The proper functioning of a PIC relies heavily on the refractive index to remain relatively constant over time. (The refractive index of a material is temperature-dependent). Undesired variations in the refractive index can cause the performance of a PIC to grossly deviate from its intended performance. This occurs because the propagation constant associated to an optical mode is related to the refractive index of the material.

Thus, it is critically important that heat generated within the package be promptly extracted outside the package. This is not straightforward because the ASICs, due to their digital nature, are power hungry and as a result can produce substantial levels of heat. Some ASICs of the types described herein, for example, use power levels as high as 100 W in some embodiments. Additionally, the PICs themselves produce heat, although the PICs operate at significantly lower power levels, e.g., 1 W.

The inventors have developed package designs that allow for efficient heat extraction from the ASICs and the PICs. The packages developed by the inventors are designed so that heat is extracted from both sides of a package. For example, heat produced by the ASICs may be extracted from the top side of a package and heat produced by the PICs may be extracted from the bottom side of the package, or vice versa. This scheme forces heat produced by the ASICs to travel preferentially away from the PICs, thus limiting variations in refractive index.

FIG. 2C is a schematic diagram illustrating a representative package design, in accordance with some embodiments. As shown, the package includes an interposer 370 (e.g., a silicon interposer or an organic interposer). ASICs 300 are disposed on a first side of the interposer, and PICs 350 are disposed on the second, opposite side of the interposer. Each ASIC 300 may be a chip including a digital controller 100 and each PIC 350 is a chip including a photonic accelerator 150. Interposer 370 includes conductive traces placing the PICs in communication with the ASICs. Use of interposers is particularly useful in those embodiments in which the number of PICs (four in the example of FIG. 2B) differs from the number of ASICs (two in the example of FIG. 2B). In some embodiments, the interposer is a passive component in that it includes conductive traces but does not include circuits (e.g., transistors) requiring electric power to operate. In this way, the interposer can be fabricated inexpensively.

A thermally conductive member 250 is placed in thermal contact with the ASICs on the first side of the interposer and a thermally conductive member 252 is placed in thermal contact with the PICs on the second side of the interposer. The thermally conductive members may be made of any suitable thermally conductive material, including indium and silicon epoxies. Placing a component in thermal contact with another component involves creating a conductive thermal path between the two components. This may be achieved in numerous ways, for example by placing the components in direct physical contact or in contact through a thermal interface material (TIM).

As shown, in the arrangement of FIG. 2C, heat produced by the ASICs is extracted from the top side of the package. In this way, the heat travels preferentially away from the PICs, thereby limiting refractive index variations. On the other hand, heat produced by the PICs is extracted from the bottom side of the package. The arrows labeled “heat” have different dimensions to indicate that heat produced by the ASICs is generally greater than heat produced by the PICs.

### IV. Packages

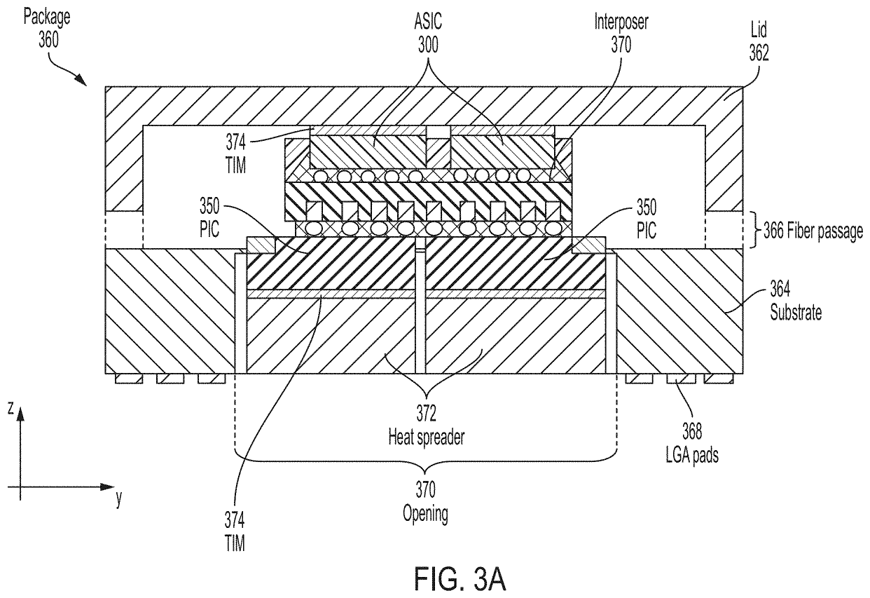

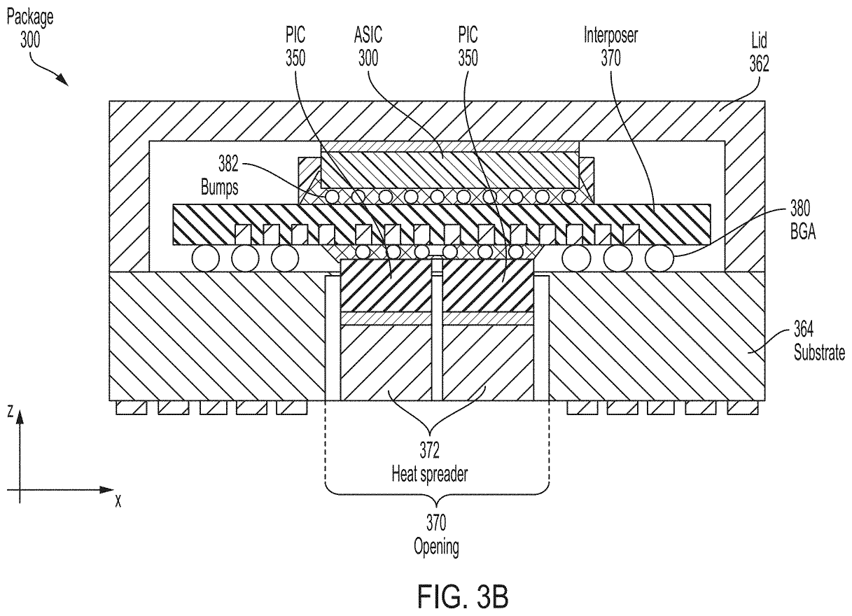

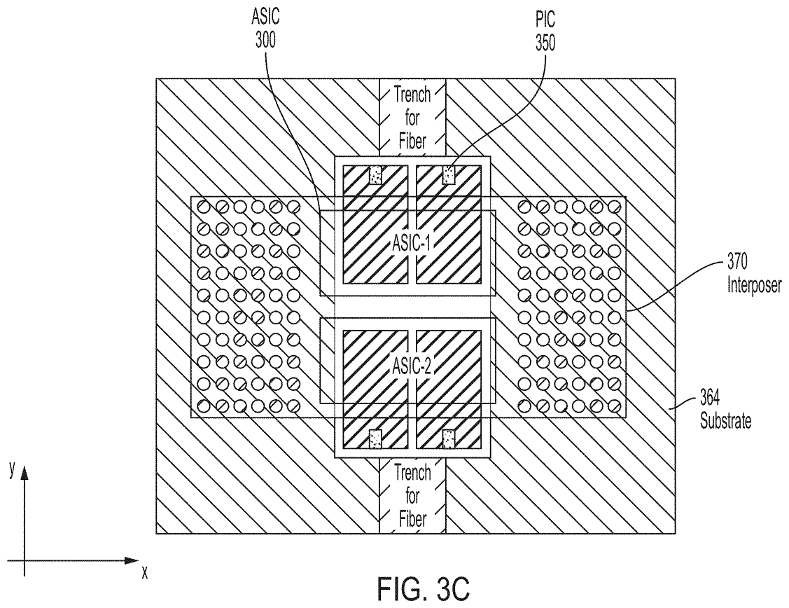

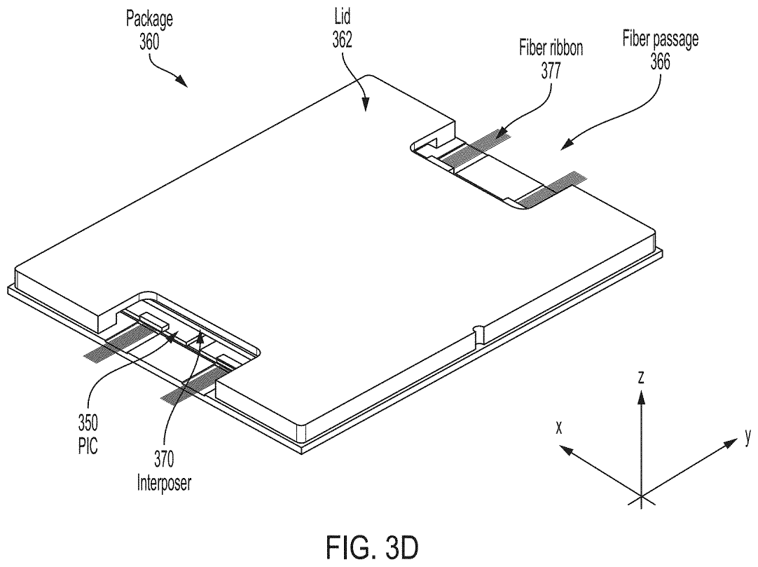

FIG. 3A-3D are schematic views of a package implemented in accordance with the principle depicted in FIG. 2C. FIG. 3A is a cross sectional view taken in the yz-plane, FIG. 3B is a cross sectional view taken in the xz-plane, FIG. 3C is a top view and FIG. 3D is a perspective view. It should be noted that the figures are not drawn to scale. Package 360 includes an interposer 370, ASICs 300, PICs 350, substrate 364, lid 362 and heat spreader 372, among other components. In this example, the package includes four PICs and two ASICs, though the packages described herein are not limited to any particular number of chips.

Substrate 364 may be made of any suitable material, including organic and inorganic materials. For example, substrate 364 may be made of a laminate of organic layers. Land grid array (LGA) pads may be defined on the bottom surface of the substrate, though other types of connections are also possible. Use of LGA pads allows the substrate to be mounted to a printed circuit board (PCB) via a socket. In other embodiments, however, the substrate may be mounted directly to a PCB by ball grid array (BGA) solder balls, and without sockets.

An opening 370 may be formed through the entire thickness of substrate 364, thereby creating a passage from the top surface of the substrate to the bottom surface of the substrate. In some embodiments, either the PICs or the ASICs are disposed in the opening. (In some embodiments, there may be more than one opening, each chip being disposed within a respective opening). In the example of FIG. 3A, the PICs are disposed in the opening. A chip may be attached to the substrate in any suitable way, including by glues or by mechanically anchoring a chip to the substrate. In some embodiments, the top surface of the PICs 350 is raised with respect to the top surface of 364, thereby allowing fibers to be connected to the side of the PICs (e.g., edge coupling). Fiber passages 366 are defined through lid 362. These passages allow insertion of fiber ribbons through the lid. Each ribbon may include multiple fibers configured to edge couple to the PICs. Fiber trenches may be formed on the top surface of the substrate to accommodate the fibers.

Interposer 370 sits in part on the PICs and in part on the top surface of the substrate. Because the top surfaces of the PICs are slightly raised relative to the top surface of the substrate, the interposer may include two distinct sets of connections. A first set of connections electrically couples the interposer to the substrate. A second set of connections electrically couples the interposer to the PICs. To account for the fact that the surface of the substrate may be lower than the surfaces of the PICs, the connections of the first set may be larger (e.g., taller) than the connections of the second set. For example, the connections coupling the interposer to the substrate may form a ball grid array (BGA), and the connections coupling the interposer to the PICs may be solder bumps or Cu pillars. In one example, the first set of connections has a pitch equal to 400 μm and the second set of connections has a pitch equal to 100 μm. An underfill fills the region between the interposer and the PICs. ASICs 300 are disposed on top of interposer 370. Bumps 382 place the ASICs in electrical communication with the interposer. The interposer, in turn, routes signals between the ASICs and the PICs.

Lid 362 encloses the chips inside the package. Lid 362 may be made of a high thermally conductive material such as Ni-plated Cu or other high thermal conductivity material such as SiC. Lid 362 may sit on the top surface of the substrate, and may be in thermal contact with the top surfaces of the ASICs 300. For example, a TIM 374 is disposed between the lid and the ASICs. Lid 362 serves as thermally conductive member 250 of FIG. 2C in that it extracts heat produced by the ASICs from the top side of the package.

Heat spreader 372 fills at least a portion of opening 372. Heat spreader 372 may be a unitary piece or may include multiple distinct pieces. Heat spreader 372 is in thermal contact with the bottom surfaces of the PICs 350. For example, a TIM 374 is disposed between the thermally conductive member and the PICs. Heat spreader 372 serves as thermally conductive member 252 of FIG. 2C in that it extracts heat produced by the PICs from the bottom side of the package.

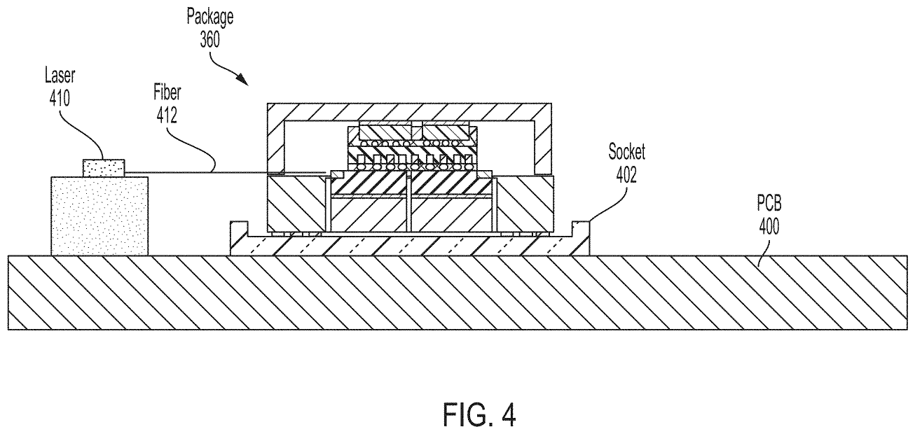

FIG. 4 is a side view illustrating a package 360 mounted on a PCB 400 via a socket 402. A laser 410 is also mounted on the PCB. Fibers 412 pass through passages 366 and optically couple the laser to the PICs. Laser 410 is disposed outside package 360. Thus, in some embodiments, package 360 lacks lasers disposed therein.

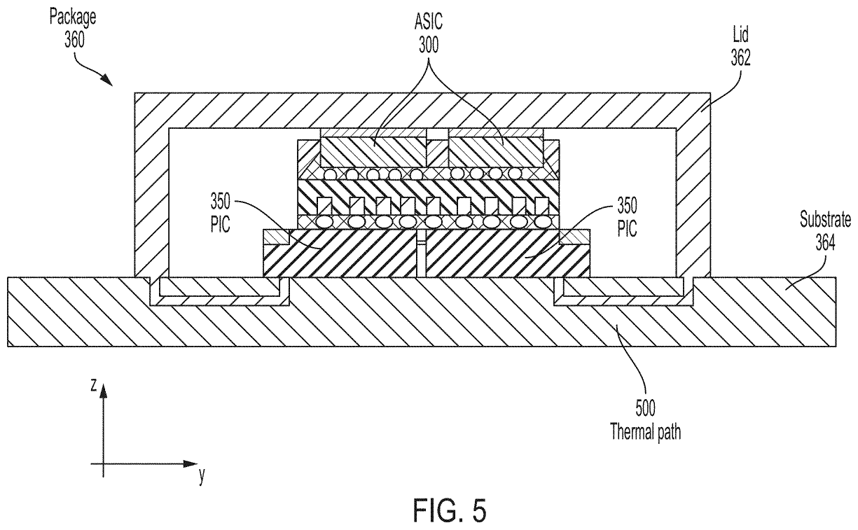

FIG. 5 illustrates an alternative package implementation. This package is similar to the package of FIG. 3A in that it includes an interposer between ASICs and PICs, and in that a lid covers the chips and thermally contacts the ASICs. However, unlike the package of FIG. 3A, in this package heat produced by the PICs is also extracted from the top side of the package. A thermal path 500 places the PICs in thermal contact with the lid. Thermal path 500 may include conductive pillars (or vias) and conductive traces. In some embodiments, the PICs may have TSVs. In this way, electrical connections to the substrate are enabled while also allowing for the thermal path scheme.

### V. Fabrication

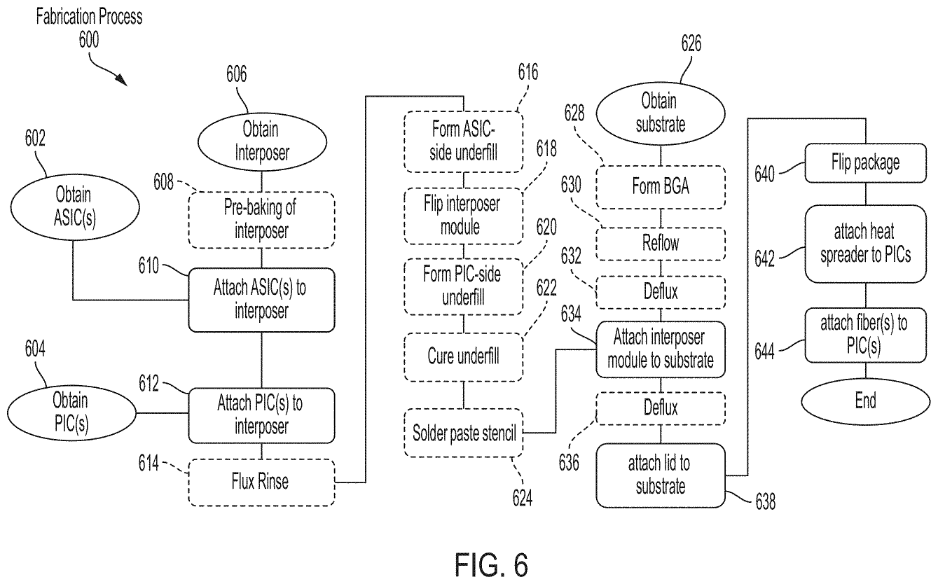

FIG. 6 is a flowchart of a method (600) for fabricating an electronic-photonic package, in accordance with some embodiments. In this figure, dashed blocks represent optional fabrication steps. It should be noted that, unless otherwise specified, fabrication method 600 need not be performed in the order in which the steps of FIG. 6 are presented (though some embodiments may be performed in that order). As described in detail below, in some embodiments, fabrication of an electronic-photonic package may involve flip-chip techniques.

At step 602, one or more ASICs are obtained. For example, the ASICs may be received at a packaging facility from an ASIC manufacturing facility. The ASICs may be obtained in the form of individual chips, or in the form of a wafer. If the latter, the ASICs may be singulated from the wafer, for example using a saw blade or other suitable tools. Each ASIC may be pre-patterned (at the ASIC manufacturing facility) with a digital controller of the types described herein, such as digital controller 100. Patterning the ASICs may be performed prior to step 602.

At step 604, one or more PICs are obtained. For example, the PICs may be received at the packaging facility from a PIC manufacturing facility. As for the ASICs, the PICs may be obtained in the form of individual chips, or in the form of a wafer. If the latter, the PICs may be singulated from the wafer, for example using dicing techniques (e.g., stealth dicing). Each PIC may be pre-patterned (at the PIC manufacturing facility) with a photonic accelerator of the types described herein, such as photonic accelerator 150.

At step 606, an interposer is obtained. For example, the interposer may be received at the packaging facility from an interposer manufacturing facility. The interposer may be pre-patterned as described in connection with FIGS. 3A-3D. At step 608, the interposer may be pre-baked.

At step 610, the ASICs may be attached to the interposer. This may be performed using pick and place techniques. In some embodiments, attachment of the ASICs to the interposer may involve a reflow and/or a deflux.

At step 612, the PICs may be attached to the interposer. This may be performed using pick and place techniques. In some embodiments, attachment of the PICs to the interposer may involve a reflow. The PICs may be attached to the opposite side of the interposer relative to the ASICs, as shown for example in FIG. 3A. At step 614, the interposer module (comprising the interposer with the ASICs and PICs attached thereto) may go through a flux rinse.

At step 616, an underfill is formed on the ASIC-side of the interposer. At this stage, the underfill is a curable dielectric material. At step 618, the interposer module is flipped. At step 620, an underfill is formed on the PIC-side of the interposer. In other embodiments, steps 616 and 620 may be flipped, so that an underfill is formed on the PIC-side of the interposer prior to flipping the interposer and an underfill is formed on the ASIC-side of the interposer after the flipping step. At step 622, the underfills are cured. At step 624, solder paste stencil may be printed on one side of the interposer module, e.g., the PIC-side. Additionally, or alternatively, flux printing may be performed on BGAs previously formed on one side of the interposer module, e.g., the PIC-side.

At step 626, a substrate is obtained. For example, the substrate may be received at the packaging facility from a substrate manufacturing facility. In some embodiments, at step 626, the substrate is etched to form an opening, as shown for example in FIG. 3A (see opening 370). At step 628, a BGA is formed on the substrate so that when the interposer module is attached to the substrate, the BGA balls land on the BGA pads of step 624. At step 630, the substrate undergoes a reflow. At step 632, the substrate undergoes a deflux. At step 634, the interposer module is attached to the substrate. This may be performed using pick and place techniques. In some embodiments, attachment of the interposer module to the substrate may involve a reflow.

Subsequently, a first thermally conductive member is placed in thermal contact with the ASICs and a second thermally conductive member is placed in thermal contact with the PICs. The thermally conductive members may be placed in opposite sides of the interposer modules. As an example, at step 638, a thermally conductive lid is mounted to the substrate so that the lid is in thermal contact (either directly or through a TIM) to the ASICs. At step 640, the package is flipped. At step 642, a heat spreader is placed in thermal contact with the PICs. In some embodiments, the heat spreader is inserted from the bottom side of the package, through the opening defined in the substrate. In other embodiments, steps 638 and 642 may be flipped, so that lid is attached prior to flipping the package and the heat spreader is formed after the flipping step. Further, in some embodiments, the PICs may be on the top side of the package and the ASICs may be on the bottom side of the package. In these embodiments, the lid contacts the PICs and the heat spreader contacts the ASICs.

At step 644, fibers are attached to the PICs.

### VI. Additional Comments

Having thus described several aspects and embodiments of the technology of this application, it is to be appreciated that various alterations, modifications, and improvements will readily occur to those of ordinary skill in the art. Such alterations, modifications, and improvements are intended to be within the spirit and scope of the technology described in the application. It is, therefore, to be understood that the foregoing embodiments are presented by way of example only and that, within the scope of the appended claims and equivalents thereto, inventive embodiments may be practiced otherwise than as specifically described. In addition, any combination of two or more features, systems, articles, materials, and/or methods described herein, if such features, systems, articles, materials, and/or methods are not mutually inconsistent, is included within the scope of the present disclosure.

Also, as described, some aspects may be embodied as one or more methods. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

The definitions, as defined and used herein, should be understood to control over dictionary definitions, definitions in documents incorporated by reference and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some case and disjunctively present in other cases.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The terms “approximately,” “substantially,” and “about” may be used to mean within ±10% of a target value in some embodiments. The terms “approximately,” “substantially,” and “about” may include the target value.

Use of ordinal terms such as “first,” “second,” “third,” etc., in the claims to modify a claim element does not by itself connotate any priority, precedence, or order of one claim element over another or the temporal order in which acts of a method are performed, but are used merely as labels to distinguish one claim element having a certain name from another claim element having a same name (but for use of the ordinal term) to distinguish the claim elements.

Also, the phraseology and terminology used herein is for the purpose of description and should not be regarded as limiting. The use of “including,” “comprising,” “having,” “containing,” “involving,” and variations thereof herein, is meant to encompass the items listed thereafter and equivalents thereof as well as additional items.

What is claimed is:

1. An electronic-photonic package comprising:
a substrate having an opening defined therethrough;
an application specific integrated circuit (ASIC) and a photonic integrated circuit (PIC), wherein a first chip between the ASIC and the PIC is disposed in the opening;
an interposer, wherein the first chip is coupled to a first side of the interposer and a second chip between the ASIC and the PIC is coupled to a second side of the interposer opposite the first side;
a heat spreader disposed in the opening and in thermal contact with the first chip; and
a thermally conductive lid in thermal contact with the second chip.

2. The electronic-photonic package of claim 1, wherein the opening is defined from a top surface of the substrate to a bottom surface of the substrate.

3. The electronic-photonic package of claim 1, wherein the first chip is the PIC and the second chip is the ASIC, such that the heat spreader is in thermal contact with the PIC and the thermally conductive lid is in thermal contact with the ASIC.

4. The electronic-photonic package of claim 1, wherein the first chip is disposed at least partially in the opening.

5. The electronic-photonic package of claim 1, wherein the thermally conductive lid has a fiber passage defined therethrough.

6. The electronic-photonic package of claim 5, wherein a fiber passing through the fiber passage is configured to edge couple to the PIC.

7. The electronic-photonic package of claim 1, wherein the substrate has a top surface facing the interposer and a bottom surface, wherein the electronic-photonic package further comprise land grid array (LGA) pads coupled to the bottom surface of the substrate.

8. The electronic-photonic package of claim 1, wherein the PIC comprises a photonic accelerator configured to perform matrix multiplication in an optical domain, and wherein the ASIC comprises a digital controller configured to control the photonic accelerator.

9. The electronic-photonic package of claim 1, wherein the electronic-photonic package lacks lasers disposed therein.

10. An electronic-photonic processor comprising:
a plurality of photonic integrated circuits (PICs), each PIC comprising a photonic accelerator configured to perform matrix multiplication in an optical domain;
an application specific integrated circuit (ASIC) configured to control at least one of the photonic accelerators;
an interposer, wherein the plurality of PICs are coupled to a first side of the interposer and the ASIC is coupled to a second side of the interposer opposite the first side;
a first thermally conductive member in thermal contact with at least one of the PICs; and
a second thermally conductive member in thermal contact with the ASIC, wherein the first thermally conductive member faces the first side of the interposer, and the second thermally conductive member faces the second side of the interposer.

11. The electronic-photonic processor of claim 10, further comprising a substrate having an opening formed therethrough, wherein the interposer is mounted on the substrate, and wherein either the first thermally conductive member or the second thermally conductive member is disposed in the opening.

12. The electronic-photonic processor of claim 11, wherein the substrate has a top surface facing the interposer and a bottom surface, wherein the electronic-photonic processor further comprise land grid array (LGA) pads coupled to the bottom surface of the substrate.

13. The electronic-photonic processor of claim 11, wherein the second thermally conductive member is in contact with the substrate.

14. The electronic-photonic processor of claim 10, wherein the digital controller is configured to control the photonic accelerators to perform matrix multiplication in the optical domain in parallel on a tile-by-tile basis.

15. The electronic-photonic processor of claim 10, wherein the photonic accelerators comprise photonic multipliers configured to perform scalar multiplications in the optical domain.

16. The electronic-photonic processor of claim 10, wherein the photonic accelerators comprise photonic adders configured to perform scalar additions in the optical domain.

17. The electronic-photonic processor of claim 10, wherein the plurality of PICs, the ASIC, the interposer, and the first and second thermally conductive members form a package, and wherein the electronic-photonic processor further comprises a laser disposed outside the package.

18. The electronic-photonic processor of claim 10, wherein the first thermally conductive member comprises conductive pillars.

19. A method for fabricating an electronic-photonic package, comprising:
obtaining a substrate, an application-specific integrated circuit (ASIC), a photonic integrated circuit (PIC) and an interposer;
forming an interposer module by attaching the ASIC to a first side of the interposer and the PIC to a second side of the interposer;
attaching the interposer module to the substrate;
placing a first thermally conductive member in thermal contact with the ASIC; and
placing a second thermally conductive member in thermal contact with the PIC.

20. The method of claim 19, further comprising:
forming a first underfill on the first side of the interposer;
flipping the interposer; and
subsequent to flipping, forming a second underfill on the second side of the interposer.

21. The method of claim 19, wherein placing the second thermally conductive member in thermal contact with the PIC comprises inserting the second thermally conductive member through an opening formed in the substrate.

22. The method of claim 19, further comprising flipping the substrate, so that placing the first thermally conductive member in thermal contact with the ASIC is performed prior to flipping the substrate and placing the second thermally conductive member in thermal contact with the PIC is performed after flipping the substrate.
